(19) United States
(12) Patent Application Publication
(10) Pub. No.: US 2013/0140525 A1
(43) Pub. Date: Jun. 6, 2013

(54) GALLIUM NITRIDE GROWTH METHOD ON SILICON SUBSTRATE

(71) Applicants: Chi-Ming CHEN, Zhubei City (TW); Po-Chun LIU, Hsinchu City (TW); Hung-Ta LIN, Hsinchu City (TW); Chung-Yi YU, Hsinchu (TW); Chia-Shiung TSAI, Hsinchu (TW); Ho-Yung David HWANG, Hsinchu (TW)

(72) Inventors: Chi-Ming CHEN, Zhubei City (TW); Po-Chun LIU, Hsinchu City (TW); Hung-Ta LIN, Hsinchu City (TW); Chung-Yi YU, Hsinchu (TW); Chia-Shiung TSAI, Hsinchu (TW); Ho-Yung David HWANG, Hsinchu (TW)

(73) Assignee: TAIWAN SEMICONDUCTOR MANUFACTURING COMPANY, LTD., Hsinchu (TW)

(21) Appl. No.: 13/308,997

(22) Filed: Dec. 1, 2011

(51) Int. Cl. H01L 29/205; H01L 21/20

(52) U.S. Cl. 257/22; 438/478; 257/E29.091; 257/E21.09

(57) ABSTRACT

A semiconductor structure includes a silicon substrate; more than one bulk layer of group-III/group-V (III-V) compound semiconductor atop the silicon substrate; and each bulk layer of the group III-V compound is separated by an interlayer.

### TECHNICAL FIELD

This disclosure relates generally to semiconductor circuit manufacturing processes and, more particularly, to forming group-III/group-V (III-V) compound semiconductor films on silicon substrates.

### BACKGROUND

Group-III/group-V compound semiconductors (often referred to as III-V compound semiconductors), such as gallium nitride (GaN) and its related alloys, have been under intense research in recent years due to their promising applications in electronic and optoelectronic devices. The large band gap and high electron saturation velocity of many III-V compound semiconductors also make them excellent candidates for applications in high temperature and high-speed power electronics. Particular examples of potential electronic devices employing III-V compound semiconductors include high electron mobility transistors (HEMT) and other heterojunction bipolar transistors. Particular examples of potential optoelectronic devices employing III-V compound semiconductors include blue light emitting diodes and laser diodes, and ultra-violet (UV) photo-detectors.

Epitaxially grown films of the III-V compound semiconductor GaN are used in these devices. Unfortunately, GaN epitaxial films must be grown on substrates other than GaN, because it is extremely difficult to obtain GaN bulk crystals due to the high equilibrium pressure of nitrogen at the temperatures typically used to grow bulk crystals. Owing to the lack of feasible bulk growth methods for GaN substrates, GaN is commonly deposited epitaxially on dissimilar substrates such as silicon, SiC, and sapphire (Al₂O₃). Particularly, research is focused on using silicon as the growth substrate for its lower cost as compared to other growth substrates and subsequent processing capabilities. However, the growth of GaN films on silicon substrates is difficult, because silicon has a lattice constant and thermal expansion coefficient different than those of GaN. If the difficulties of growing GaN films on silicon substrates could be overcome, silicon substrates would be attractive for GaN growth given their low cost, large diameter, high crystal and surface quality, controllable electrical conductivity, and high thermal conductivity. The use of silicon substrates would also provide easy integration of GaN based optoelectronic devices with silicon-based electronic devices.

The large stresses created by growing a GaN film on a silicon substrate may cause the substrate to bow or break. This bowing may cause several adverse effects. First, a great number of defects (dislocations) may be generated or propagated in the crystalline GaN films. Second, the thicknesses of the resulting GaN films will be less uniform; causing undesirable electrical property shifts in the final device. Third, large stressed GaN films may simply break. New methods for forming III-V compound semiconductor films while overcoming the above-discussed drawbacks are thus needed.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1 and 2 illustrate a process for forming a group-III group-V semiconductor film known to the inventors;

FIG. 3 is a process flow diagram showing operations in accordance with various embodiments of the present disclosure;

FIGS. 4(a) through 4(e) are cross-sectional views of stages in the manufacturing of various embodiment in accordance with the present disclosure; and

FIGS. 5(a) and 5(b) are example semiconductor structures according to various embodiments of the present disclosure.

### DETAILED DESCRIPTION

The making and using of the present embodiments are discussed in detail below. It should be appreciated, however, that the present disclosure provides many applicable inventive concepts that can be embodied in a wide variety of specific contexts. The specific embodiments discussed are merely illustrative of specific ways to make and use the invention and do not limit the scope of the disclosure.

A novel method for forming group-III to group-V (referred to as III-V hereinafter) semiconductor films and the resulting structures are provided. Throughout the description, the term “III-V compound semiconductor” refers to compound semiconductor materials comprising at least one group III element and one group-V element. The term “III-N compound semiconductor” refers to a III-V compound semiconductor in which the group V element is nitrogen. The required stages of manufacturing an illustrative embodiment of the present disclosure are illustrated. Those skilled in the art will recognize that other manufacturing steps may need to take place before or after the described stages in order to produce a complete device. Throughout the various views and illustrative embodiments of the present disclosure, like reference numbers are used to designate like elements.

As discussed, growing a thick GaN film, up to a few microns, for example 5 microns, has many challenges, including mismatching CTEs (coefficient of thermal expansion between the III-N material and silicon) and mismatching lattice constants. One previous solution uses several layers of slightly different material to reduce the stresses at the interface between the silicon wafer and the group III-V compound semiconductor layer. On top of the silicon wafer a thin nucleation layer may be grown. For example, an aluminum nitride (AlN) layer with a thickness of about 150-300 nm may be grown on the silicon wafer. On the nucleation layer a graded layer may be grown. In some cases, a graded layer would have a concentration gradient with reducing aluminum content and increasing gallium content. The graded layer may have a thickness of about 500 to 1000 nm with the top most gradient to be mostly gallium nitride. On the grade layer a bulk gallium nitride layer is deposited. The bulk gallium nitride layer can be deposited with less interfacial stress with the underlying layer; however, the bulk gallium nitride layer can only be deposited up to about 3 microns. A thicker bulk layer still results in breakage and excess defect.

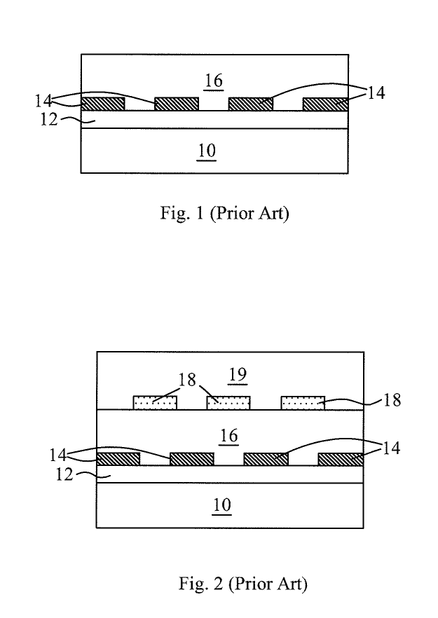

Another previous solution is the epitaxial lateral overgrowth (ELOG) technique. FIGS. 1 and 2 illustrate an ELOG process known to the inventors. Referring to FIG. 1, substrate 10 is provided. Under-layer 12, which comprises a nitride semiconductor (i.e., a III-V compound semiconductor in which the group V element is nitrogen), such as GaN, is formed on substrate 10. Dielectric masks 14 are then formed on under-layer 12. Next, a III-V compound semiconductor layer 16 is epitaxially grown, wherein the growth includes a vertical growth component and a lateral overgrowth component, which eventually results in a continuous III-V compound layer 16. FIG. 2 shows an expansion of the ELOG technique, an additional mask layer 18 is formed, followed by the growth of another III-V compound layer 19. Again, the growth includes a vertical growth and a lateral growth, so that III-V compound layer 19 eventually becomes a continuous layer.

The ELOG techniques shown in FIGS. 1 and 2 suffer from drawbacks. First, the silicon in the substrate may react with the nitrogen in under-layer 12 to form silicon nitride. The undesirably formed silicon nitride acts as an amorphous overcoat at the interface between silicon substrate 10 and under-layer 12. The amorphous overcoat may adversely affect the film quality of the subsequently grown III-V compound semiconductor films because the silicon nitride has a higher resistivity. In addition, the higher resistivity may also preclude formation of vertical devices, in which two contacts to the device are formed on opposite sides of substrate 10. The two dielectric mask technique of FIG. 2 requires the epitaxial growth process to be performed twice, because the same epitaxial chamber cannot be used to deposit and pattern the second dielectric mask. Thus wafer in process is heated and cooled two or more times, which heightens the CTE mismatch.

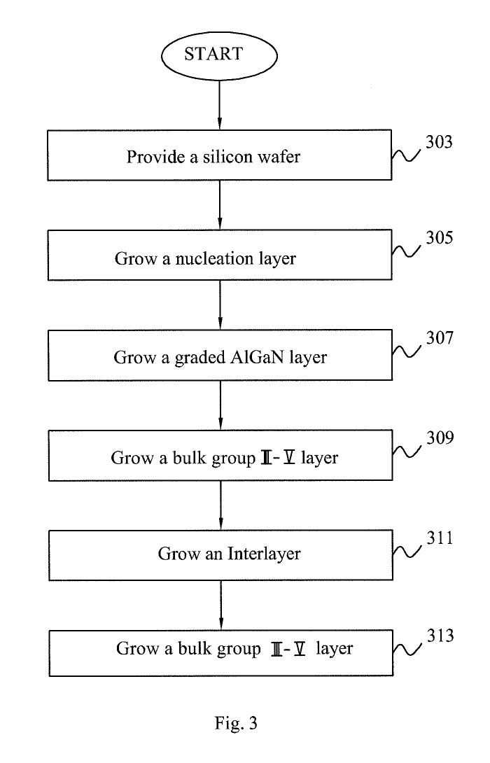

The present disclosure provides a structure and a method to form III-V compound semiconductor films with less strain and thereby increasing the yield and reducing defects. Referring now to FIG. 3, the flowchart of the method 301, at operation 303, a first silicon wafer is provided. The silicon wafer may have a crystal orientation having a Miller index of [111]. The silicon wafer may be between about 600 to about 1500 microns thick. A thicker silicon wafer may be stronger and is less likely to break; however, the increased volume increases the bowing when the wafer is cooled. A thinner silicon wafer would suffer less bowing, but is less strong.

In operation 305 of FIG. 3, a thin nucleation layer can be grown on the surface of the silicon wafer. For example, an aluminum nitride (AlN) layer with a thickness of about 150-300 nm may be grown on the silicon wafer. After the AlN nucleation layer is grown on the silicon wafer, in operation 307 of FIG. 3, a graded layer may be grown on the AlN nucleation layer. In one embodiment the graded layer is composed of aluminum Gallium Nitride (AlGaN). In some cases, a graded layer would have a concentration gradient with reducing aluminum content and increasing gallium content.

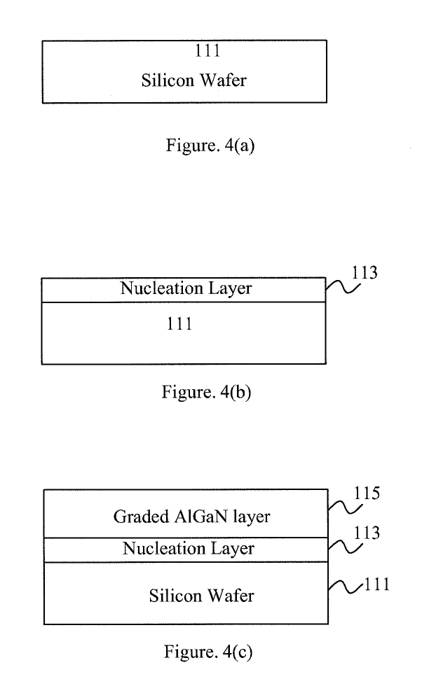

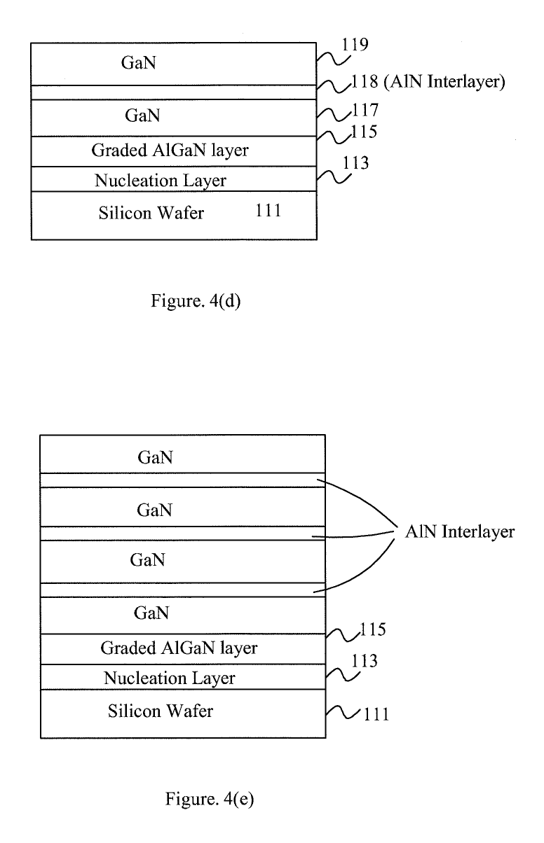

In one embodiment, the graded AlGaN layer is epitaxially grown. The graded AlGaN layer is mostly defect free and shown as layer 115 in FIG. 4C. The graded group III-V layer may have a thickness about 0.5 microns to about 3 microns. In one example, the graded group III-V layer has a thickness of about 2 microns.

According to various embodiments, the graded group III-V layer may be a superlattice layer with AlGaN and Al(Ga)N superlattices. The concentrations in the Al(Ga)N superlattice may be defined as Alₓ(Ga₁₋ₓ)N, with the x value greater than about 0.8 and up to 1. Thus, the Al(Ga)N superlattice may have an x value of 1 so that the superlattice is simply AlN. The superlattice layer may be formed by alternating an Al(Ga)N layer of about 3-8 nm thick, or about 5 nm, for example, and a GaN layer of about 10-30 nm thick, or about 20 nm, for example.

In some cases, the gallium concentration may increase from one side of the graded layer to the other side. In other words, the Al(Ga)N superlattice closest to the AlN lateral growth layer would have little or no gallium concentration, and the Al(Ga)N superlattice closest to the top of the graded layer would have little or no aluminum. A superlattice layer may be formed using metal organic CVD (MOCVD) or metal organic vapor phase epitaxy (MOVPE), molecular beam epitaxy (MBE), atomic layer deposition (ALD), electron-gun, or sputtering methods.

In other embodiments, layer 115 may be a graded layer having increasing concentrations of gallium and decreasing concentrations of aluminum from the lateral growth layer side to the bulk gallium nitride side. The concentration variation may be gradual or stepwise in several layers. During epitaxial growth, the concentration variation may be achieved by switching on and off various gases and changing flow rates and pressures without removing the wafer-in-process from the chamber. The use of layer 115 is found to reduce the CTE mismatch between the bulk gallium nitride and the silicon wafer.

Referring back to FIG. 3, in operation 309, a first bulk group III-V layer is epitaxially grown. The first bulk group III-V layer is shown as layer 117 in FIG. 4D. The first bulk group III-V layer 116 may be a gallium nitride (GaN) layer with a thickness of between about 0.5 microns and about 3 microns, for example, at about 3 microns. The bulk GaN layer is grown under high temperature conditions. The process may be metal organic CVD (MOCVD), metal organic vapor phase epitaxy (MOVPE), plasma enhanced CVD (PECVD), remote plasma enhanced CVD (RP-CVD), molecular beam epitaxy (MBE), hydride vapor phase epitaxy (HYPE), chloride vapor-phase epitaxy (Cl-VPE), and liquid phase epitaxy (LPE). Using metal organic vapor phase epitaxy (MOVPE) using gallium-containing precursor and nitrogen-containing precursor. The gallium-containing precursor includes trimethylgallium (TMG), triethylgallium (TEG), or other suitable chemical. The nitrogen-containing precursor includes ammonia (NH₃), tertiarybutylamine (TBAm), phenyl hydrazine, or other suitable chemical.

Referring to FIG. 3, in operation 311, after the first bulk group III-V layer (i.e., the first GaN layer 117) is grown on the graded AlGaN layer, a thin AlN interlayer 118 is grown atop the first bulk group III-V layer. In certain embodiments, the AlN interlayer 118 is grown using a low temperature epitaxial process. The process may be metal organic CVD (MOCVD), metal organic vapor phase epitaxy (MOVPE), plasma enhanced CVD (PECVD), remote plasma enhanced CVD (RPCVD), molecular beam epitaxy (MBE), hydride vapor phase epitaxy (HYPE), chloride vapor-phase epitaxy (Cl-VPE), and liquid phase epitaxy (LPD). The process temperature may be about 900 to about 1100 degrees Celsius. The process pressure under which the AlN interlayer 118 can be grown should be about 50-300 Torr. The AlN interlayer 118 should have an epitaxy thickness from 30-200 nm.

Then, in operation 313, as shown in FIG. 3, after the thin AlN interlayer 118 is grown on the first bulk group III-V layer (i.e., the first GaN bulk layer 117), a second GaN bulk layer 119 is grown on top of the AlN interlayer 118. The second bulk group III-V layer 118 may be a gallium nitride (GaN) layer with a thickness of between about 0.5 microns and about 3 microns, for example, at about 3 microns. The process conditions for growing the second bulk group III-V layer 119 should be the same as those for growing the first bulk group III-V layer 117.

FIG. 4(d) shows the semiconductor structure after operation 313, whereby the second bulk group III-V layer 119 (i.e., the second bulk GaN layer) is grown. FIG. 4(d) shows that the thin AlN interlayer 118 is “sandwiched” between the two GaN bulk layers 117 and 119.

Having an AlN interlayer positioned between the two bulk group III-V layers has significant advantages. Due to the lattice difference between the silicon substrate and the GaN bulk layer, the stress between the silicon substrate and the GaN bulk layer causes defects from the generation of threading dislocations. The defects will propagate upwards into the GaN bulk layer. While having a transition region between the silicon wafer and the GaN bulk layer, for example a buffer layer such as graded AlGaN layer, may help to reduce the stress, its effectiveness in stopping the defect propagation is limited.

The AlN interlayer 118, in this embodiment, acts as a barrier to limit the propagation of defects traveling from the first GaN bulk layer into the second GaN bulk layer. The AlN interlayer 118 also provides an additional transition region to further reduce the inter-lattice stress in the GaN bulk region of the semiconductor structure.

In another embodiment, as shown in FIG. 4(e), more than one AlN interlayers are placed in the GaN region. For example, FIG. 4(e) shows four GaN bulk layers, each GaN bulk layer is separated by a different AlN interlayer. In this embodiment, after the second GaN bulk layer is grown on the first AlN interlayer, a second AlN interlayer is grown. Thereafter, a third GaN bulk layer is grown on the second AlN interlayer, and a third AlN interlayer is grown on the third GaN bulk layer. Finally a fourth and final GaN bulk layer is grown on the third AlN interlayer. In this embodiment, each AlN interlayer has a thickness between 10-100 nm, and each GaN bulk layer has a thickness between 1-2 micrometers. This multiple AlN interlayer, multiple GaN bulk layer configuration further reduces the defect density in the GaN bulk layers and the AlN interlayers act as multiple barriers to propagation of defects.

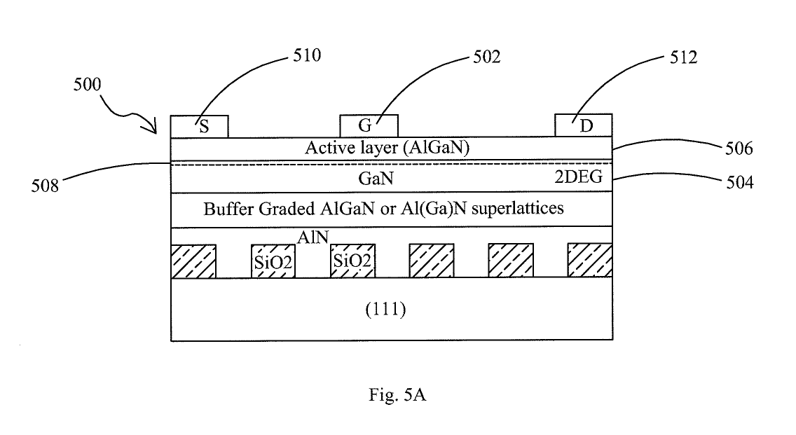

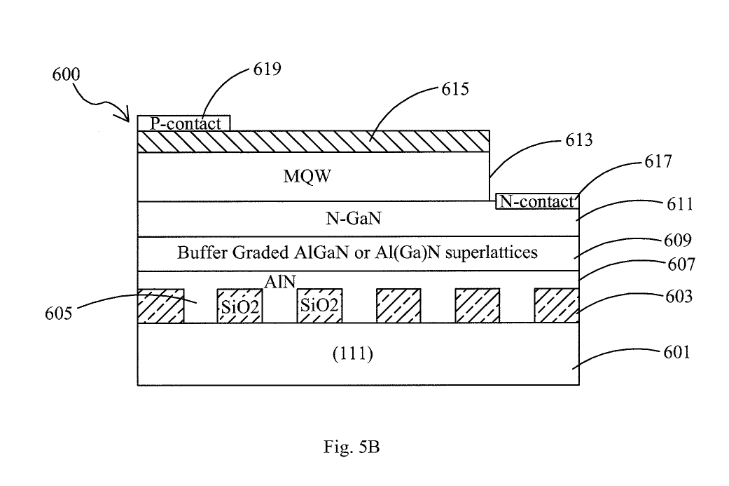

Depending on the device to be manufactured, the bulk GaN may be doped or undoped. FIG. 5A shows an example power transistor device 500 according to various embodiments of the present disclosure. The bulk gallium nitride layer 504 is a channel layer for the power transistor device, which may be a high electron mobility transistor (HEMT). FIG. 5A shows an active layer 506 on top of the bulk GaN layer. The active layer 506, also referred to as donor-supply layer, is grown on the channel layer 504. An interface is defined between the channel layer 504 and the donor-supply layer 506. A carrier channel 508 of two-dimensional electron gas (2-DEG) is located at the interface. In at least one embodiment, the donor-supply 506 refers to an aluminum gallium nitride (AlGaN) layer (also referred to as the AlGaN layer 506). The AlGaN layer 506 can be epitaxially grown on the GaN layer 504 by MOVPE using aluminum-containing precursor, gallium-containing precursor, and nitrogen-containing precursor. The aluminum-containing precursor includes TMA, TEA, or other suitable chemical. The gallium-containing precursor includes TMG, TEG, or other suitable chemical. The nitrogen-containing precursor includes ammonia, TBAm, phenyl hydrazine, or other suitable chemical. The AlGaN layer 506 has a thickness in a range from about 5 nanometers to about 50 nanometers. In other embodiments, the donor-supply layer 506 may include an AlGaAs layer, or AlInP layer.

A band gap discontinuity exists between the AlGaN layer 506 and the GaN layer 504. The electrons from a piezoelectric effect in the AlGaN layer 506 drop into the GaN layer 504, creating a very thin layer 508 of highly mobile conducting electrons in the GaN layer 504. This thin layer 108 is referred to as a two-dimensional electron gas (2-DEG), forming a carrier channel (also referred to as the carrier channel 508). The thin layer 508 of 2-DEG is located at an interface of the AlGaN layer 506 and the GaN layer 504. Thus, the carrier channel has high electron mobility because the GaN layer 504 is undoped or unintentionally doped, and the electrons can move freely without collision with the impurities or substantially reduced collision.

The semiconductor structure 500 also includes a source feature 510 and a drain feature 512 disposed on the AlGaN layer 506 and configured to electrically connect to the carrier channel 508. Each of the source feature and the drain feature comprises a corresponding intermetallic compound. The intermetallic compound is at least partially embedded in the AlGaN layer 506 and a top portion of the GaN layer 504. In one example, the intermetallic compound comprises Al, Ti, or Cu. In another example, the intermetallic compound comprises AlN, TiN, Al₃Ti or AlTi₂N.

The intermetallic compound may be formed by constructing a pattern metal layer in a recess of the AlGaN layer 506. Then, a thermal annealing process may be applied to the pattern metal layer such that the metal layer, the AlGaN layer 506 and the GaN layer 504 react to form the intermetallic compound. The intermetallic compound contacts the carrier channel 508 located at the interface of the AlGaN layer 506 and the GaN layer 504. Due to the formation of the recess in AlGaN layer 506, the metal elements in the intermetallic compound may diffuse deeper into the AlGaN layer 506 and the GaN layer 504. The intermetallic compound may improve electrical connection and form ohmic contacts between the source/drain features and the carrier channel 508. In one example, the intermetallic compound is formed in the recess of the AlGaN layer 506 thereby the intermetallic compound has a non-flat top surface. In another example, intermetallic compound overlies a portion of the AlGaN layer 506.

The semiconductor structure 500 also includes a gate 502 disposed on the AlGaN layer 506 between the source and drain features. The gate 502 includes a conductive material layer which functions as the gate electrode configured for voltage bias and electrical coupling with the carrier channel 508. In various examples, the conductive material layer may include a refractory metal or its compounds, e.g., tungsten (W), titanium nitride (TiN) and tantalum (Ta). In one example, the gate 502 is directly disposed on the AlGaN layer 506. In another example, a dielectric layer (not shown) is formed between the gate 502 and the AlGaN layer 506. The dielectric layer may include silicon oxide (SiO₂), silicon nitride (Si₃N₄), aluminum oxide (Al₂O₃), tantalum oxide (Ta₂O₅), titanium oxide (TiO₂), zinc oxide (ZnO₂), or hafnium oxide (HfO₂). The dielectric layer has a thickness in a range from about 3 nm to about 500 nm. The dielectric layer provides isolation to prevent gate leakage and further improve device switching speed.

The HEMT 500 includes a relatively thick layer of bulk gallium nitride, which allows high power operation with voltages greater than a hundred volts. The channel has very low resistivity, which allows very high frequency operation. Electrical properties of gallium nitride based HEMT compare favorably to silicon and silicon carbide based devices and with very competitive costs. Specifically, low gate capacitance and low on-resistance permits much higher frequency switching converters than competing silicon-based transistors. The present disclosure provides a structure and method to form the thick gallium nitride layer with less strain and defects.

Various embodiments of the present disclosure also pertain to a light-emitting diode (LED) as shown in FIG. 5B. The LED 600 is formed on a silicon substrate 601. On the silicon substrate is the patterned layer 603. The deposition and patterning operations for the patterned layer 603 is as disclosed in conjunction with operations 305 and 307 of FIG. 3. For vertical devices, it may be advantageous to use conductive materials instead of dielectric material for layer 603, so that patterned layer 603 also has the function of conducting carriers in vertical optoelectronic devices, in which the two contacts are formed on opposite sides of substrate. However, the material of layer 603 is resistant to epitaxial growth.

A vertical growth layer 605 of group III-V semiconductor material, for example, AlN, is embedded in the patterned layer 603. A lateral growth layer 607 is grown over the vertical growth layer 605 and completely covers the patterned layer 603 so as to form a continuous epitaxial film. Next, a graded group III-V layer 609, for example, AlGaN film, or a group III-V superlattice layer 609, for example, Al(Ga)N superlattice layer, is formed over the lateral growth layer, as described in association with operation 313 of FIG. 3. Over the graded group III a bulk gallium nitride 611 is grown. Depending on the type of LED, the bulk gallium nitride film 611 is either n-doped or p-doped. Doped gallium nitride film is grown by adding dopants during epitaxial growth. The type of dopant and concentration determines the amount of doping. The bulk gallium nitride layer for an LED may have different requirements than the bulk gallium nitride layer for a HEMT. In addition to difference in doping, thickness of the bulk gallium nitride film used in the respective devices are also different.

On the doped gallium nitride layer, a multiple quantum well (MQW) layer 613 is formed including alternating (or periodic) layers of active material. Depending on the LED color to be emitted during operation, different materials are included in these alternating layers, for example, gallium nitride and indium gallium nitride for a blue LED. In one embodiment, the MQW layer 613 includes ten layers of gallium nitride and ten layers of indium gallium nitride, where an indium gallium nitride layer is formed on a gallium nitride layer, and another gallium nitride layer is formed on the indium gallium nitride layer, and so on and so forth. The light emission efficiency of the structure depends on the number of layers of alternating layers and thicknesses. The thickness of the MQW layer 613 may be about 10-2000 nm, about 100-1000 nm, or for example, about 100 nm.

Another doped group III-V layer 615 is formed on the MWQ layer 613. This doped layer has an opposite doped conductivity from the doped bulk gallium nitride film 611. The MQW layer 613 and the doped layer 615 are patterned and etched down to or into the doped bulk gallium nitride layer 611 to define an area for the contact pad 617. Note that an isolating material may be added between the MQW sidewall and the contact pad 617 so as to electrically separate them. If the bulk gallium nitride layer 611 has n-type doped conductivity, then the contact pad 617 is an n-type contact. If the bulk gallium nitride layer has p-type conductivity, then the contact pad 617 is a p-type contact. Additional layers of material may be added over the doped layer 615 before the other contact pad 619 is formed. Both contact pads 617 and 619 may be made of one or several layers of metal and other conductive material. In some LEDs, wires are bonded to the contact pads to external terminals. When voltage is applied via the wires between the contact pads, the LED emits light. Other contact methods include metal bonding and flip chip bonding. In other embodiments, the contacts are formed on opposite sides of the LED in a vertical chip formation. In the vertical chip formation, the contacts may be metal bonded, soldered, or wire bonded to terminals connected to the electricity source.

The embodiments of the present disclosure may have other variations. For example, one or more layers of III-V compound semiconductor layers may be formed to further improve the quality of the resulting III-V compound semiconductor layers or the patterned layer may include more than one layer. Certain embodiments of the present disclosure have several advantageous features. By separately growing the vertical growth layer and the lateral growth layer in some circumstances, very different process conditions may be used. The vertical growth results in the generation of fewer vertical dislocations in the lateral growth layer. The use of the patterned layer and superlattice layer also reduce lattice mismatch strain. Hence the quality of the III-V compound semiconductor layers is improved.

Although the present disclosure and its advantages have been described in detail, it should be understood that various changes, substitutions and alterations can be made herein without departing from the spirit and scope of the disclosure as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure, processes, machines, manufacture, compositions of matter, means, methods, or steps that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A semiconductor structure comprising:
a silicon substrate;
a first bulk layer of group III-V compound semiconductor over the silicon substrate;
an interlayer over the first bulk layer of group III-V compound semiconductor; and
a second bulk layer of group III-V compound semiconductor over the interlayer.

2. The semiconductor structure of claim 1, further comprising a graded group III-V superlattice layer.

3. The semiconductor structure of claim 1, further comprising an AlN nucleation layer.

4. The semiconductor structure of claim 1, wherein the interlayer is made of AlN.

5. The semiconductor structure of claim 1, wherein the first bulk layer of group III-V compound is GaN.

6. The semiconductor structure of claim 2, wherein the graded group III-V superlattice layer has a thickness between 500 and 1000 nm.

7. The semiconductor structure of claim 3, wherein the AlN nucleation layer has a thickness between 150 and 300 nm.

8. The semiconductor structure of claim 1, wherein a second interlayer is over the second bulk layer of group III-V compound semiconductor.

9. The semiconductor structure of claim 1, wherein a third bulk layer of group III-V compound semiconductor is over the second interlayer.

10. The semiconductor structure of claim 1, wherein more than two bulk layers of group III-V compound semiconductor are over the silicon substrate.

11. The semiconductor structure of claim 10, wherein each bulk layer of group III-V compound semiconductor is separated by an interlayer.

12. The semiconductor structure of claim 1, wherein the bulk layer is about 0.5 to about 5 microns.

13-18. (canceled)

19. The method of claim 1, wherein the semiconductor structure is a light emitting diode.

20. The method of claim 1, wherein the semiconductor structure is a high electron mobility transistor.

21. A semiconductor structure comprising:
a silicon substrate;
a nucleation layer over the silicon substrate;
a graded layer over the nucleation layer;
a plurality of bulk layers of group III-V compound over the graded layer; and
an interlayer between each adjacent bulk layers of the plurality of bulk layers.

22. The semiconductor structure of claim 21, wherein the graded layer comprises aluminum gallium nitride (AlGaN), and a concentration of gallium increases as a distance from the silicon substrate increases.

23. The semiconductor structure of claim 22, wherein the concentration of gallium increases in a step-wise manner.

24. The semiconductor structure of claim 21, wherein the graded layer comprises:
a plurality of aluminum gallium nitride (AlₓGa₁₋ₓN) layers, wherein x ranges from 0.8 to 1; and
a plurality of gallium nitride (GaN) layers arranged in an alternating fashion with the plurality of AlₓGa₁₋ₓN layers.

25. The semiconductor structure of claim 24, wherein a first layer of the plurality of AlₓGa₁₋ₓN layers has a higher aluminum concentration than a second layer of the plurality of AlₓGa₁₋ₓN layer, wherein the second layer is further from the silicon substrate than the first layer.

26. A semiconductor structure comprising:
a silicon substrate;
a graded layer over the silicon substrate, wherein the graded layer comprises
a plurality of aluminum gallium nitride (AlₓGa₁₋ₓN) layers; and
a plurality of gallium nitride (GaN) layers arranged in an alternating fashion with the plurality of AlₓGa₁₋ₓN layers;
a first bulk layer of group III-V compound over the graded layer;
a second bulk layer of group III-V compound over the first bulk layer; and
an interlayer between the first and second bulk layers.
